(19) United States
(12) Patent Application Publication
(10) Pub. No.: US 2025/0244432 A1
(43) Pub. Date: Jul. 31, 2025

(54) MAGNETIC RESONANCE IMAGING APPARATUS AND IMAGE RECONSTRUCTION METHOD

(71) Applicant: FUJIFILM Corporation, Tokyo (JP)

(72) Inventor: Yusuke HOSHINO, Tokyo (JP)

(73) Assignee: FUJIFILM Corporation, Tokyo (JP)

(21) Appl. No.: 18/951,117

(22) Filed: Nov. 18, 2024

(30) Foreign Application Priority Data
Jan. 30, 2024 (JP) 2024-012056

(51) Int. Cl. G01R 33/565; G01R 33/561

(52) U.S. Cl. CPC G01R 33/56509; G01R 33/5611

(57) ABSTRACT

Provided is a technique of improving accuracy of image reconstruction accompanied by body motion correction processing.

In a case in which a period during which a body motion occurs is defined as a first period based on a result of detecting a body motion of an examination target disposed in a static magnetic field space, a second period that includes the first period and that is longer than the first period is specified. In measurement data of the examination target collected by magnetic resonance imaging, data collected in the second period is removed or corrected to generate an image of the examination target. As the second period, a detection timing error can be compensated for by extending a start end side of the first period, and data collected at a time at which a signal is unstable due to the body motion can be removed by extending a terminal end side.

### CROSS-REFERENCE TO RELATED APPLICATIONS

The present application claims priority under 35 U.S.C. § 119 to Japanese Patent Application No. 2024-012056, filed Jan. 30, 2024. Each of the above application(s) is hereby expressly incorporated by reference, in its entirety, into the present application.

### BACKGROUND OF THE INVENTION

### 1. Field of the Invention

The present invention relates to a magnetic resonance imaging apparatus (hereinafter, referred to as an MRI apparatus), and particularly relates to an MRI apparatus having a body motion processing function of detecting a body motion and reconstructing an image in which an influence of the body motion is suppressed.

### 2. Description of the Related Art

In an examination using the MRI apparatus, an examination target is disposed in a static magnetic field space, nuclear magnetic resonance is induced within the examination target, nuclear magnetic resonance signals are collected, and an image of the examination target is reconstructed by performing an operation on the nuclear magnetic resonance signals. The MRI examination target is usually a human being (hereinafter, referred to as a subject) such as a patient, and a sudden motion (referred to as a body motion, which is distinguished from a periodic motion such as breathing) such as a sneezing or coughing may occur in addition to a motion such as a respiratory motion during the examination. Since the nuclear magnetic resonance signals are signals that has been given positional information by applying a gradient magnetic field, in a case in which such a body motion occurs, the gradient magnetic field is applied to a position different from the original gradient magnetic field, and the image reconstruction itself may be difficult, for example, an artifact may occur in the image reconstructed from the nuclear magnetic resonance signals.

In the MRI apparatus, various measures are taken against an influence of such a body motion. For example, in the technique disclosed in JP2023-043001A, the body motion of the examination target is detected from a camera video, and a pulse sequence is divided and executed depending on whether or not the body motion is within an allowable range. In addition, a method of surveilling the motion of the subject using a signal (called a navigator echo) obtained by MRI is also widely used (JP2012-000389A, JP2008-154887A). In imaging using navigator data, the navigator echo is generated separately from a nuclear magnetic resonance signal (hereinafter, referred to as an image signal) for obtaining an image of the subject, and the motion of the subject is estimated from a change in data (hereinafter, referred to as navigator data) consisting of a series of navigator echoes obtained in time series, and correction of the image signal or a reconstructed image is performed using a result of the estimation.

In a case in which the body motion is detected from the navigator echo or the camera video, control is also performed, such as re-acquiring an image signal acquired in a case in which a large body motion is detected or adopting an image reconstruction method that does not use the image signal (for example, JP2022-022669A).

### SUMMARY OF THE INVENTION

However, in some cases, a body motion artifact cannot be removed even though the body motion is detected using the techniques of the related art and data collected in a case in which the body motion is detected is processed.

One reason for this, which depends on accuracy of means for detecting the body motion, is considered to be that there is an error between a timing of detecting the body motion and an actual time point of occurrence of the body motion. In addition, even though the body motion is stopped after the body motion is detected by a camera or a navigator echo, the body motion may cause a steady state of an echo signal to collapse, which may cause an artifact. In addition, there is a possibility that a fine motion remains inside the examination target that is not captured by the camera or the like. In these cases, the artifact cannot be sufficiently removed by the method in the related art.

An object of the present invention is to remove a body motion artifact that could not be removed by body motion processing using body motion detection means in the related art and to further improve accuracy of body motion artifact suppression.

In order to solve the above problem, the present invention sets a second period in which a body motion artifact is expected in comparison with a first period that can be detected by body motion detection means in the related art, and performs image reconstruction by performing appropriate processing on measurement data collected in the second period.

That is, the MRI apparatus according to an aspect of the present invention comprises: an RF transmitting unit that applies a high-frequency magnetic field pulse to an examination target placed in a static magnetic field space; an RF receiving unit that receives a nuclear magnetic resonance signal emitted by the examination target; a gradient magnetic field generation unit that generates a gradient magnetic field pulse for applying a magnetic field gradient to a static magnetic field; an image generation unit that generates an image of the examination target using measurement data consisting of the nuclear magnetic resonance signal; and a body motion processing unit that processes body motion information of the examination target. The body motion processing unit detects a first period during which a body motion occurs in the examination target, and then specifies a second period that includes the first period and that is longer than the first period, and the image generation unit removes or corrects data collected in the second period in the measurement data, and generates the image of the examination target.

In addition, an image reconstruction method according to another aspect of the present invention comprises: defining, based on a result of detecting a body motion of an examination target disposed in a static magnetic field space, a period during which the body motion occurs as a first period, and specifying a second period that includes the first period and that is longer than the first period; and removing or correcting data collected in the second period in measurement data of the examination target collected by the magnetic resonance imaging, and generating an image of the examination target.

According to the present invention, by extending the period (the period during which the body motion occurs) detected by the body motion detection means to at least one of the preceding period or the succeeding period, it is possible to remove an influence of a non-stationary change due to the body motion, which cannot be captured by the body motion detection means but causes the artifact, on an image, thereby achieving high-level body motion suppression image reconstruction.

### BRIEF DESCRIPTION OF THE DRAWINGS

FIG. 1 is an overall view showing an outline of an MRI apparatus.

FIG. 2 is a functional block diagram of a processor of the MRI apparatus.

FIG. 3 is a diagram showing an example of a flow of imaging and body motion processing.

FIGS. 4A1 and 4A2 are diagrams showing an example of a pulse sequence including navigator data collection.

FIG. 4B is a diagram showing another example of a pulse sequence including navigator data collection.

FIGS. 5A and 5B are diagrams showing still another example of a pulse sequence including navigator data collection.

FIG. 6 is a diagram schematically showing detection of a body motion and a body motion detection period (first period).

FIG. 7 is a diagram illustrating specification of a second period of a body motion processing unit.

FIG. 8 is a diagram illustrating an example of a method of determining a terminal end side of the second period.

FIG. 9 is a diagram illustrating an example of image reconstruction in which body motion information is reflected.

### DESCRIPTION OF THE PREFERRED EMBODIMENTS

Hereinafter, an embodiment of an MRI apparatus according to an embodiment of the present invention will be described.

There are various types of MRI apparatuses, such as a horizontal magnetic field type and a vertical magnetic field type, depending on a direction of a generated static magnetic field, and a permanent magnet type, a normal electromagnetic type, and a superconducting magnet type, depending on a magnet that generates the static magnetic field. The present invention can be applied to a known MRI apparatus. In addition, a shape of a static magnetic field space in which a subject is placed is a cylindrical space, a planar space sandwiched between upper and lower magnets, or the like, and the present invention can be applied to any of these shapes.

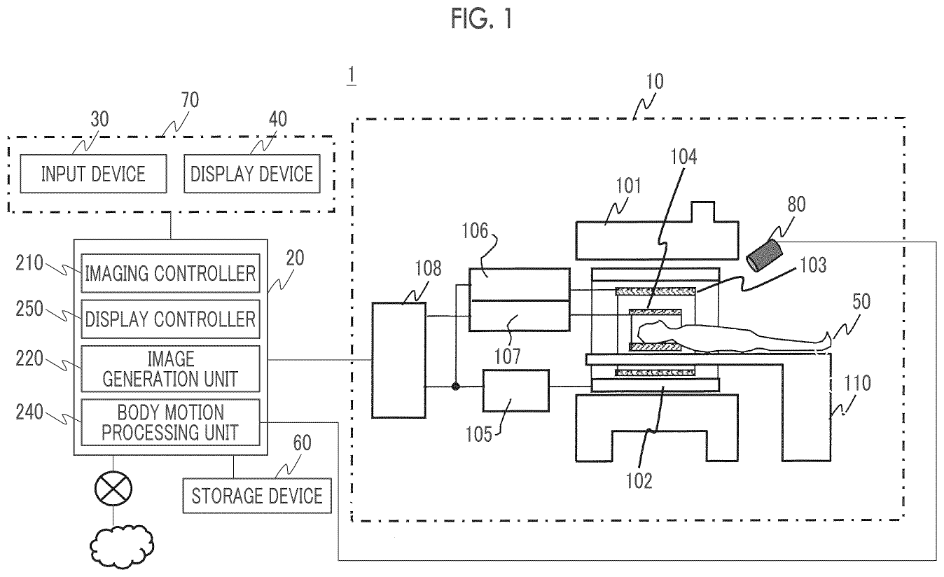

First, an outline of the MRI apparatus to which the present invention is applied will be described with reference to FIG. 1.

As shown in FIG. 1, an MRI apparatus 1 comprises a static magnetic field generation device (static magnetic field generating magnet) 101 that generates a static magnetic field, an RF transmitting unit 106 that applies a high-frequency magnetic field pulse to an examination target 50 placed in a space in which a static magnetic field is generated by a static magnetic field magnet, an RF receiving unit 107 that receives a nuclear magnetic resonance signal emitted by the examination target 50, a gradient magnetic field coil 102 and a gradient magnetic field power supply 105 (collectively referred to as a gradient magnetic field generation unit) that generate an gradient magnetic field pulse for applying a magnetic field gradient to the static magnetic field, a sequencer 108 that controls the gradient magnetic field power supply 105, the RF transmitting unit 106, and the RF receiving unit 107 in accordance with a predetermined pulse sequence, and a processor 20 that controls the entire apparatus including the sequencer 108. An RF transmission coil 103 for applying the RF pulse generated by the RF transmitting unit 106 to the subject and an RF receive coil 104 for detecting the nuclear magnetic resonance signal generated by the examination target 50 are disposed close to the examination target 50. Hereinafter, the RF transmitting unit 106, the RF receiving unit 107, and the gradient magnetic field generation unit are also collectively referred to as an imaging unit 10.

The processor 20 can be configured as a general-purpose computer comprising a memory and a CPU, and functions as a controller and an operation unit. As shown in FIG. 1, the processor 20 comprises an imaging controller 210 that controls an operation of the imaging unit 10, an image generation unit 220 that generates an image of the examination target 50 using the nuclear magnetic resonance signal received by the RF receiving unit 107, a display controller 250 that displays the image generated by the image generation unit 220, and a body motion processing unit 240 that processes the signal from detection means for detecting a body motion of the examination target during the examination, acquires the magnitude of the body motion and an occurrence time (body motion information), and performs an operation or control for removing the influence of the body motion using the body motion information. The functions of the processor 20 are implemented by the CPU uploading a predetermined program. In addition, a part of the functions can also be implemented by a programmable IC.

An input device 30 through which an operator inputs a command, data, and the like necessary for imaging, a display device 40 that displays the image generated by the image generation unit 220, a storage device 60, and the like are connected to the processor 20. The storage device 60 includes an internal storage device and an external storage device, and the external storage device may be a storage device such as a cloud connected through the Internet or the like. In addition, the MRI apparatus 1 can also exchange data with an external database (not shown) such as PACS. The input device 30 and the display device 40 are installed close to each other and function as a user interface unit 70.

In addition, the MRI apparatus 1 may comprise optical detection means such as a surveillance camera 80 for surveilling a state of the examination target 50 disposed in the static magnetic field space, and it is also possible to detect the body motion of the examination target 50 using a video from the surveillance camera 80. In this case, the body motion processing unit 240 receives information from the surveillance camera 80, and performs processing using the information together with measurement data (navigator data) from the imaging unit 10 described below as body motion information.

Since a configuration of the imaging unit 10 is the same as that of an imaging unit in the related art, description of a specific configuration will be omitted, and an outline of an operation will be described.

First, the RF pulse generated by the RF transmitting unit 106 is applied to the examination target 50 via the RF transmission coil 103, and thus nuclei (usually protons) of atoms contained in the tissue constituting the examination target 50 are excited. The RF receive coil 104 disposed close to the examination target 50 detects a nuclear magnetic resonance signal generated by nuclear magnetic resonance of the excited atomic nuclei, and the RF receiving unit 107 receives the nuclear magnetic resonance signal as a digital signal. In addition, during a period from the excitation by the RF pulse to the collection of the nuclear magnetic resonance signal, the gradient magnetic field generation unit applies a predetermined gradient magnetic field to the static magnetic field at a predetermined timing. As a result, the nuclear magnetic resonance signal is a signal having positional information, that is, an encoded signal. In addition, by applying the gradient magnetic field pulse simultaneously with the excitation, it is possible to select a specific region (slice) of the examination target and generate the nuclear magnetic resonance signal only from the selected slice.

The series of operations of the imaging unit 10 are controlled based on a pulse sequence that is a time chart in which the intensity and application timing of the RF pulse and the gradient magnetic field pulse, the signal collection time, and the like are determined. Various pulse sequences that differ depending on an imaging purpose or an imaging method are stored in advance in the storage device 60 of the MRI apparatus, and the sequencer 108 calculates a pulse sequence (referred to as an imaging sequence) to be used for imaging by using the pulse sequence selected depending on the imaging purpose or the imaging method and imaging parameters (repetition time TR, echo time TE, FOV, slice thickness, the number of slices, speed rate, and the like) set by the user, and imaging is performed in accordance with the imaging sequence.

In a case in which the MRI apparatus has a body motion processing function, the body motion of the examination target disposed in the static magnetic field space is detected in parallel with the imaging. The body motion can be detected using a method in which a video from the surveillance camera 80 or the like is used, a method in which a pulse sequence for generating a navigator echo for detecting a body motion is added to the imaging sequence and data consisting of navigator echoes acquired in time series (hereinafter, referred to as navigator data) is used, or both methods in combination, but any of these methods may be adopted. The body motion information obtained by the body motion detection means is reflected in subsequent processing such as image reconstruction.

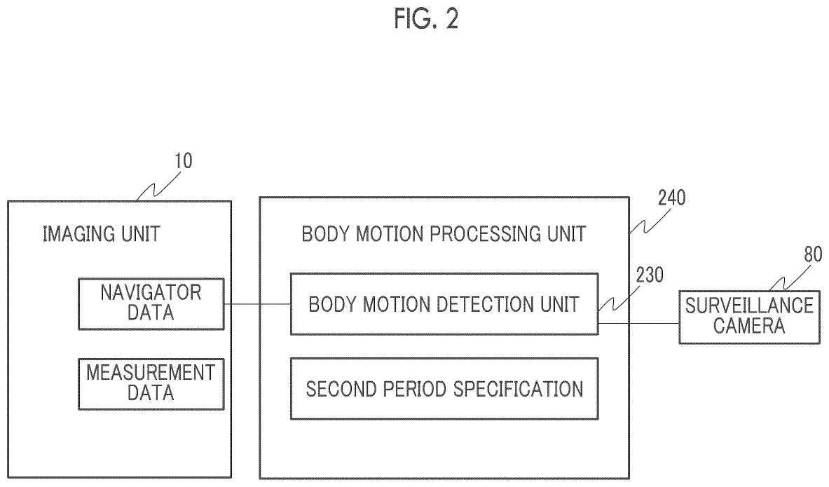

The image generation unit 220 reconstructs and generates an image by performing an operation such as Fourier transformation or an iterative operation using the nuclear magnetic resonance signal (measurement data) collected and digitized by the RF receiving unit 107, and performs image processing or the like on the generated image. In this case, the image reconstruction is performed after correction of the measurement data or removal of data affected by the body motion is performed according to a result detected by the body motion processing unit 240 (FIG. 2: body motion detection unit 230).

The image generated by the image generation unit 220 is displayed on the display device 40. Alternatively, the image may be stored in the storage device 60 or transmitted to an external database such as PACS.

The above is a general flow of imaging of the MRI apparatus having the body motion processing function, but the present invention is characterized in that, rather than using the detection result of the body motion as it is in the image reconstruction, the body motion processing unit 240 sets a range in which a detection range of the body motion detection means is widened in order to remove an influence of a body motion artifact that cannot be handled only by the body motion detection means, and performs the image reconstruction based on this range.

In consideration of the configuration of the MRI apparatus, an embodiment of the body motion processing will be described below.

### Embodiment

First, a configuration example of the body motion processing unit 240 of the embodiment is shown in FIG. 2. As shown in FIG. 2, the body motion processing unit 240 includes a body motion detection unit 230, and the body motion detection unit 230 captures at least one of a video (including an analysis result thereof) from the surveillance camera 80 or navigator data collected by the imaging unit 10 as the body motion information, analyzes the body motion information, and detects the magnitude of the body motion, a duration during which the body motion occurs, and the like. The body motion processing unit 240 performs processing of expanding the “period during which the body motion occurs (first period)” which is a detection result of the body motion detection unit 230.

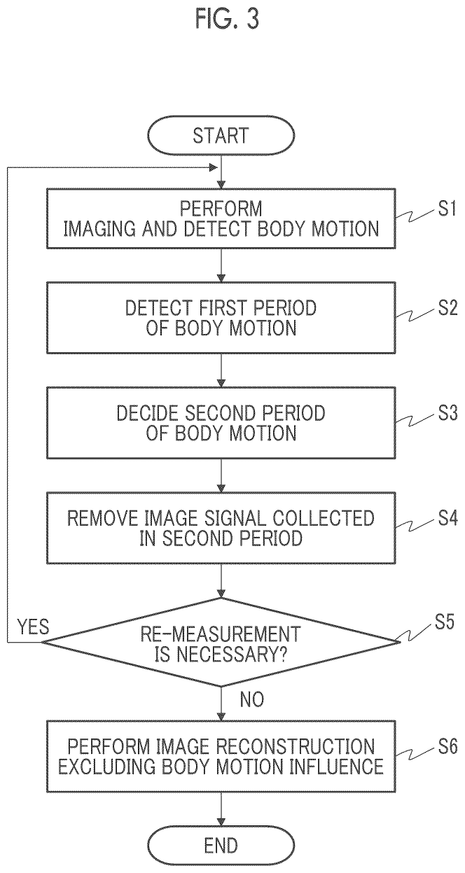

Hereinafter, processing of the present embodiment will be described along a flow of processing shown in FIG. 3.

As shown in FIG. 3, in a case in which imaging is started, detection of the body motion of the examination target is started in parallel with the imaging (S1). In a case in which the body motion is detected during the imaging, the body motion detection unit 230 decides a period during which the body motion is detected as a first period (S2). The body motion processing unit 240 sets a second period that is an extension of the first period according to a predetermined rule (S3). The imaging and the body motion detection are continued until one imaging sequence is completed. In measurement data for generating the image of the examination target (simply referred to as measurement data) obtained by the series of imaging, data collected in the second period is removed (S4).

The data may be corrected instead of being removed. Here, as an example, it is assumed that the data is removed. In a case in which the image generation unit 220 can perform image reconstruction using the measurement data after the data removal, image reconstruction is performed as is (S6). In a case in which re-measurement is required, for example in a case in which the image reconstruction cannot be performed, re-measurement is performed (S5).

Hereinafter, specific contents of each processing will be described in detail.

### Imaging and Body Motion Detection: S1

As described above, as a method of detecting the body motion, there is a method of using navigator data and a method of using a video of a camera or the like.

### Method 1: Method of Using Navigator Data

First, a method of acquiring navigator data together with imaging will be described. As a sequence for acquiring the navigator data, various methods, such as a method of acquiring a navigator echo by applying an RF pulse for generating a navigator echo separately from a pulse sequence of main imaging and a method of acquiring a navigator echo from a signal generated as an FID after an RF pulse for selecting and exciting a predetermined region in the main imaging, are known, and any of these methods can be adopted. In addition, as for a timing of generating the navigator echo, the navigator echo may be acquired before or after the echo (image signal) of the main imaging is collected, and either is possible.

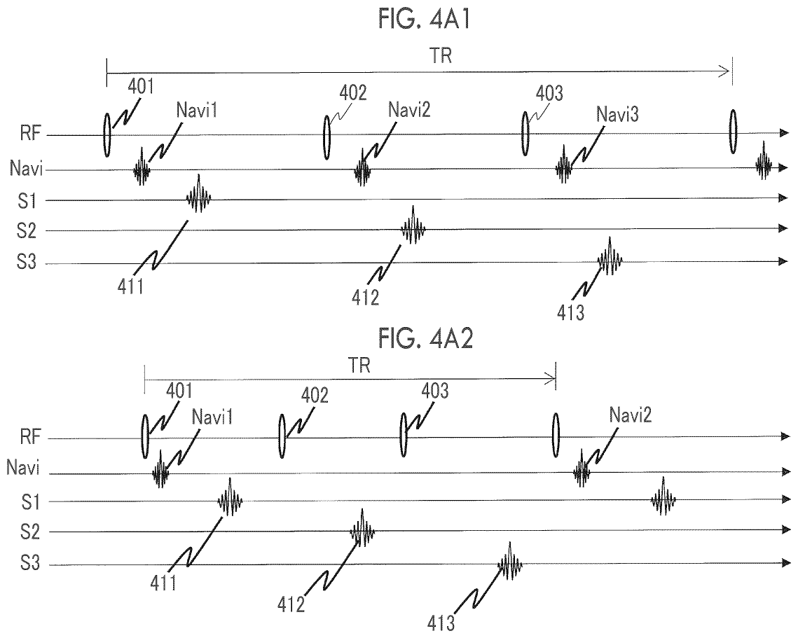

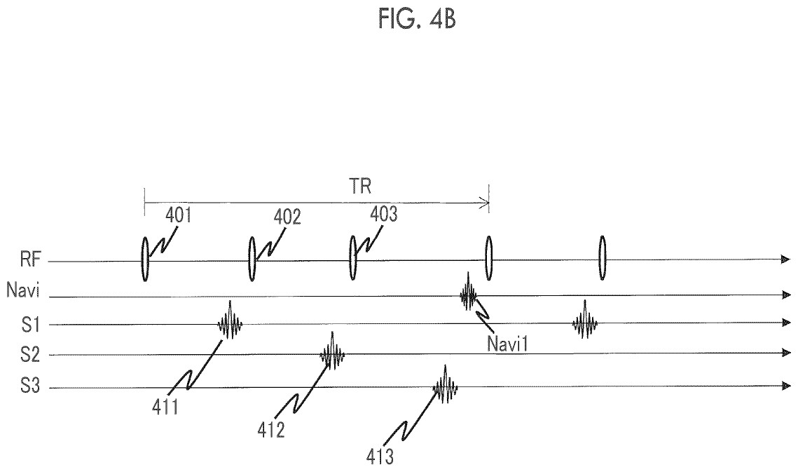

FIGS. 4A1 and 4A2, FIG. 4B, and FIGS. 5A and 5B show an example in which a navigator echo is acquired as an FID and an example in which a sequence for generating a navigator echo is executed separately from the imaging sequence to acquire a navigator echo. In these drawings, as an example, a case of multi-slice measurement in which a plurality of slices are sequentially measured within one TR is shown. However, the present invention is not limited to multi-slice. In addition, in the drawings, only the RF pulse, the navigator echo, and the image signal are shown, and the gradient magnetic field pulse is omitted, but various gradient magnetic field pulses are applied according to the imaging sequence. Note that the navigator echo is not subjected to phase encoding.

The example of FIG. 4A1 is suitable for imaging in which the TR is relatively long, and navigator echoes Navi1, Navi2, and Navi3 are acquired as the FIDs after RF pulses 401, 402, and 403 for exciting slices S1, S2, and S3, respectively, and then image signals 411, 412, and 413 are collected. In addition, the example of FIG. 4A2 is suitable for imaging in which the TR is relatively short, the navigator echo Navi1 is acquired after the RF pulse for exciting the slice S1, and the image signals 411 to 413 are collected without acquiring the navigator echo in a case of measuring the slices S2 and S3. In a case in which the image signal 411 of the slice S1 is acquired again after the TR of the slice S1, the second navigator echo Navi2 is acquired. Note that the TE is kept constant for each slice.

In the example shown in FIGS. 4A1 and 4A2, a frequency of acquiring the navigator echo, that is, a frequency of detecting the body motion can be kept to some extent by changing whether the navigator echo is acquired for each slice or for each TR according to the length of the TR. In FIGS. 4A1 and 4A2, the navigator echo is acquired after the RF pulse and before the collection of the image signal, and as shown in FIG. 4B, the navigator echo can also be acquired after the collection of the image signal. In this way, in the short TR imaging, the navigator echo acquisition for each TR is performed after the image signal collection, so that it is possible to avoid the TE extension accompanying the navigator echo acquisition and to obtain the effect of shortening the TR.

FIGS. 5A and 5B are diagrams showing an example of multi-slice measurement in which the acquisition timing of the navigator echo is different for each of a long TR and a short TR, as in FIGS. 4A1 and 4A2. In these examples, a navigator sequence including the application of the RF pulse 400 and the acquisition of the navigator echo is executed prior to or subsequent to the imaging sequence for acquiring the image signals 411 to 413. The RF pulse 400 in this case may be a selective excitation pulse for selecting the entire imaging target region, and, in a case of a pulse sequence in which a navigator sequence is inserted for each slice as in FIG. 5A, the RF pulse 400 may be a slice selective excitation pulse similar to a selective excitation pulse for each slice.

The method of acquiring the navigator data may be set in advance according to the imaging sequence and the set TR, or may be selectable by the user in consideration of the priority of the frequency of detecting the body motion or the like via the user interface unit 70 or the like.

The body motion detection unit 230 analyzes the navigator data acquired in time series during the imaging including the acquisition of the navigator data, and detects the body motion of the examination target. As a method of detecting the body motion by the body motion detection unit 230, a method of detecting the body motion from the intensity of the signal will be described.

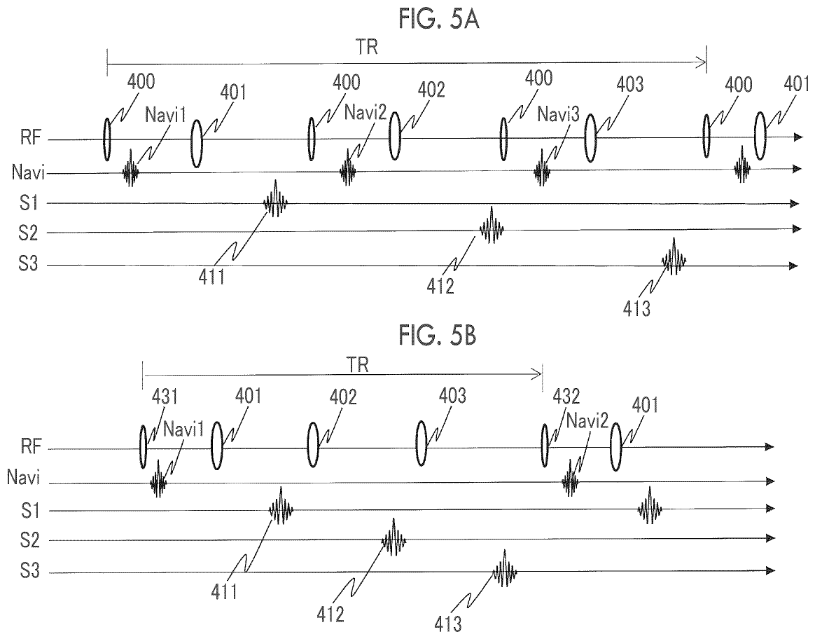

FIG. 6 schematically shows a change in signal intensity of the navigator echo. As shown in FIG. 6, in a case in which there is no motion in the examination target, the navigator echo that is not subjected to phase encoding is a signal from the entire excited region, and a signal intensity is stable. In addition, the signal intensity gently fluctuates in a part where there is a periodic motion such as a respiratory motion. Meanwhile, in a case in which a motion occurs in the measurement region due to the body motion, the signal intensity fluctuates greatly. The body motion detection unit 230 can detect the body motion by analyzing the characteristics of the fluctuation such as the magnitude and frequency of the fluctuation of the signal intensity.

For example, a reference signal obtained by averaging a plurality of navigator echoes is determined, and a root mean square (RMS) is calculated by subtracting the reference signal from each navigator echo. A navigator echo having a large error (RMS) from the reference signal is specified, a navigator echo in which an error is detected is specified, and a period between the navigator echoes in which the error is detected is defined as a first period “t1−t2”.

According to this method, it is possible to easily determine the body motion using the navigator echo, and it is possible to improve the real-time performance of the body motion detection. However, the body motion detection method of the present embodiment is not limited to this method, and it is also possible to adopt an operation using a phase difference between the navigator echo and the reference navigator echo.

### Method 2: Method of Using Camera Video

Next, a method of using optical detection means as a second method will be described. Here, as an example, a case in which a video from the surveillance camera 80 that surveils the examination target is analyzed and the displacement of the examination target is detected will be described.

One or a plurality of surveillance cameras 80 are installed near or within the static magnetic field space in which the examination target 50 is disposed. It is preferable that the camera is, for example, a wide angle camera or a stereo camera that can surveil a relatively wide range of the examination target. The camera is connected to the processor 20 of the MRI apparatus in a wired or wireless manner, and a video for each frame of the camera is captured by the processor 20. The body motion detection unit 230 of the processor 20 detects the occurrence of the body motion by capturing the video data from the camera and analyzing the camera video.

Specifically, the body motion detection unit 230 calculates the displacement vector of the subject by an operation such as optical flow for the video data for each frame. In this case, a predetermined ROI may be set for the examination target, and the displacement vector may be calculated for the ROI. Then, the displacement vector integrated from start of imaging to a predetermined time point is defined as the displacement with respect to a position (reference position) at a start time point of imaging. Alternatively, a difference between an image of a frame (a frame at a start time point of imaging) serving as a reference for the displacement vector and an image of a frame at a predetermined time point may be defined as the displacement at the time point. The displacement calculated in this manner is a gentle curve having a period of a respiratory motion in a part where the respiratory motion or the like occurs, for example, as shown in FIG. 6, but, in a case in which a sudden motion (body motion) occurs, the displacement shows the displacement corresponding to the motion.

The body motion detection unit 230 uses the range of the respiratory motion (upper limit and lower limit of displacement) as a threshold value for displacement, and in a case in which the displacement that is equal to or greater than or is equal to or less than the threshold value is detected, the body motion detection unit 230 determines that body motion is occurring and specifies the time during which the body motion is occurring.

In Method 2, since it is not necessary to insert the navigator sequence into the imaging sequence, it is possible to detect the body motion without affecting the TR or the TR of the imaging sequence.

Further, as a method of detecting the body motion, a method (Method 3) of detecting the body motion by using the navigator data and the camera video in combination may be adopted. In this case, an AND operation or an OR operation between the body motion occurrence time, which is the analysis result of the navigator data and the body motion occurrence time, which is specified by the video analysis of the camera, is performed, and the image data collected at the body motion occurrence time is specified as the removal data, using the obtained body motion occurrence time as the body motion occurrence time.

In addition, in Method 1 using the navigator data, in a case in which the timing of acquiring the navigator echo is varied depending on the length of the TR, the navigator data may be obtained for each slice, or the navigator data may be obtained only for a specific slice (for example, a central slice). In the latter case, accurate body motion information cannot be obtained in slices other than the specific slice. For slices for which the navigator data cannot be obtained, the body motion is detected using the camera video in a complementary manner.

In a case in which the slice for acquiring the navigator data is the central slice, an ROI is set in a peripheral region of the imaging region, and the camera video is analyzed. According to the method, the region of the camera video that is analyzed is limited, so that the analysis load is reduced and the real-time performance of the body motion detection is improved.

According to Method 3, the accuracy of the body motion detection can be further improved by using the camera video in combination with the body motion detection. For example, since the navigator echo is a signal from a predetermined region, a relationship with the body motion occurring in other regions cannot be grasped, but since the body motion of a region captured in the video or a region in which an ROI is set can be grasped as a whole in the camera video, the body motion that can cause the artifact can be detected without omission. Conversely, since the subject is covered with a receive coil or the like, the motion of the examination target part is not captured by the camera in some cases, but the body motion detection accuracy is improved by using the navigator data, and in particular, the accuracy can be further improved by using the camera and the navigator data in combination.

In a case in which the body motion is detected using the navigator data or the camera video, there may be an error in the detection timing of the body motion. In addition, depending on the type of the body motion, the artifact is generated until the steady state of the echo signal collapsed by the body motion is restored even after the body motion is stopped. In such a case, even in a case in which the subsequent processing is performed with only the first period detected by the body motion detection unit 230 as the period in which the body motion has occurred, the body motion artifact cannot be sufficiently suppressed.

In the next processing, the first period detected by the body motion detection unit 230 is extended to at least one of the preceding period or the succeeding period to further improve the suppression of the body motion artifact.

### Processing of Body Motion Processing Unit: S3 and S4

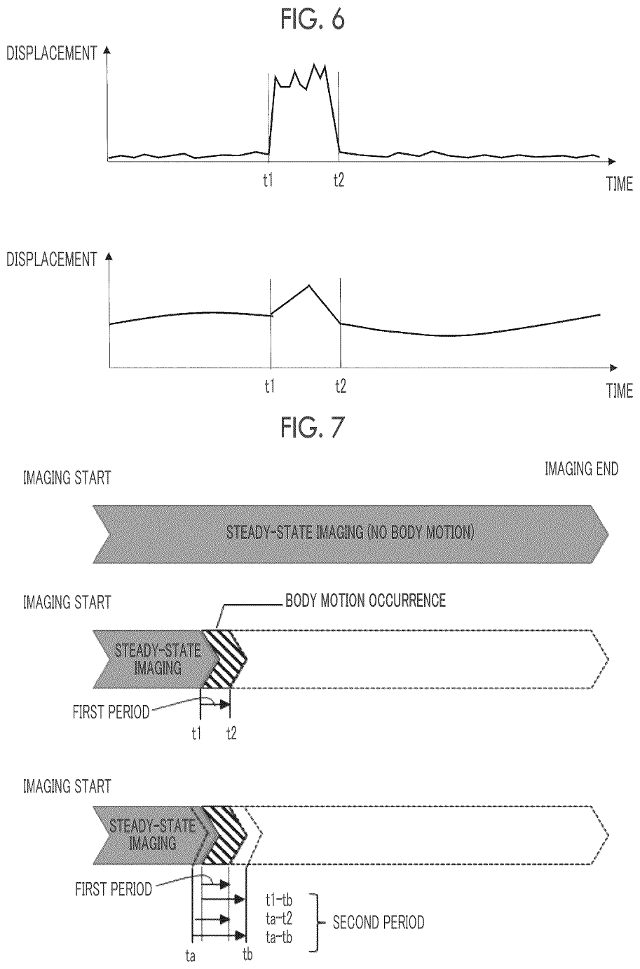

In a case in which the body motion detection unit 230 detects the first period, the body motion processing unit 240 sets an extended second period for the first period. The second period is a period that includes the first period and of which the range is extended to at least one of before or after the first period. FIG. 7 shows a method of specifying the second period. In FIG. 7, a horizontal direction indicates the progress of imaging, an upper diagram is a diagram showing a case in which there is no body motion, a middle diagram is a diagram showing the first period detected by the body motion detection unit 230, and a lower diagram is a diagram showing the second period specified by the body motion processing unit 240.

As shown on the lower side of FIG. 7, the body motion processing unit 240 sets any of a case of extending the first period (t1−t2) in a time advancement direction (second period=t1−tb), a case of including a time tracing back to the first period (second period=ta−t2), or a case of extending the first period (t1−t2) before and after (second period=ta−tb). Which case is set may be determined in advance, or may be varied depending on the method of specifying the second period or the characteristics of the body motion.

The reason for extending the second period to the start end side is mainly to compensate for an error in the detection timing of the body motion, and a predetermined value, for example, about 500 ms can be determined in advance as the time.

The extension to the terminal end side is an expansion for ensuring a period from when the steady state of the echo signal is mainly broken by the body motion until the steady state is stabilized, and in this case as well, for example, a predetermined value, for example, about 500 ms to 5000 ms may be determined in advance from a value obtained empirically.

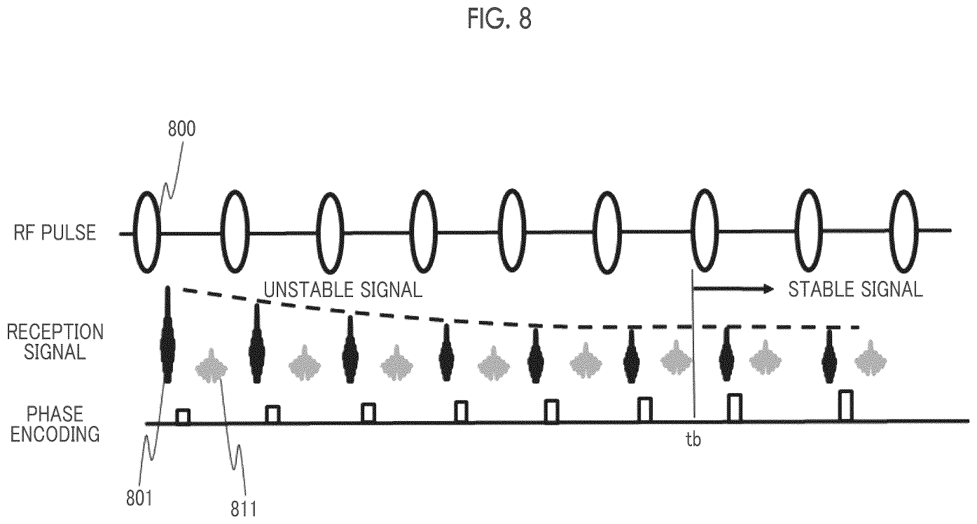

Alternatively, in a case in which the navigator data is acquired as the method of detecting the body motion, the determination may be performed from the signal intensity of the navigator echo. The navigator echo remains almost constant and stable in the absence of the body motion, but it takes a certain amount of time to return to a stable state after the body motion is stopped after the signal intensity fluctuates due to the body motion. FIG. 8 schematically shows the state. FIG. 8 is an example in which the navigator echo is acquired as the FID, in which a navigator echo 801 is acquired as the FID after an RF pulse 800, and then an image signal 811 to which the phase encoding is added is measured. Both the navigator echo and the image signal are unstable due to the influence of the body motion, but since the signal intensity of the navigator echo that is not phase-encoded is constant in a stable state, it is possible to easily detect that the signal is stable by surveilling the change in the signal intensity of the navigator echo. Therefore, the body motion processing unit 240 can detect that the stable state is reached from the change in the intensity of the navigator echo, and can specify an end time point of the second period.

For the determination of the stable state, for example, an error (RMS) of the signal intensity is obtained for each predetermined time width in the same manner as in the case of the body motion detection, and the end of the second period can be determined in a case in which an error of the signal intensity of each navigator echo is substantially zero or equal to or less than a predetermined threshold value (Condition 1), or in a case in which a difference (slope) between echoes is calculated from the signal intensity (RMS) of the navigator echo after the first period, and the slope is substantially zero or equal to or less than a predetermined threshold value (Condition 2). In the determination processing, a time at which the above-described conditions are satisfied may be determined as the end of the second period, or the end of the second period may be determined in a case in which the conditions are consecutively satisfied a plurality of times. For example, in a case in which the determination processing is satisfied three consecutive times, the end is determined. By consecutively performing the determination in this manner, it is possible to determine the stable state with higher accuracy. Conditions (1) and (2) and the determination method are examples of the stable state determination, and the present invention is not limited thereto.

In a case in which the second period is decided, the body motion processing unit 240 specifies a range of data (data to be removed: referred to as removal data) collected in the second period in the image data (k-space data) collected by the imaging unit 10 (S4).

### Imaging Controller: S5

The imaging controller 210 decides whether to use measurement data after removing the removal data specified by the body motion processing unit 240 for image reconstruction or to perform re-measurement (S5), and passes the confirmed measurement data to the image generation unit 220 in a case in which the re-measurement is not required. In a case in which the re-measurement is required, a re-measurement range is decided, and the imaging unit 10 is controlled to perform the necessary measurement.

The determination as to whether or not to perform the re-measurement can be performed, for example, by determining whether or not the data number after removing the body motion data from the data number determined by a thinning-out rate in the imaging pulse sequence can be restored by the image reconstruction processing in the image generation unit 220.

### Image Reconstruction: S6

In a case in which there is no body motion during the collection of the image signal, the image generation unit 220 performs image reconstruction using normal fast Fourier transformation FT, a parallel imaging PI operation according to a speed rate, iterative reconstruction, and the like. In a case in which the body motion occurs, the image reconstruction is performed using k-space data from which the specified removal data has been removed. In an image reconstruction method of k-space data having a smaller number of data than the original number of data, in a case in which the number of data to be removed is small, the image reconstruction may be performed by fast Fourier transformation after performing a method of replacing the removed data with zero, correction using Hermitian symmetry of the k-space, or the like. Alternatively, an iterative reconstruction method of correcting missing data through an iterative operation may be adopted.

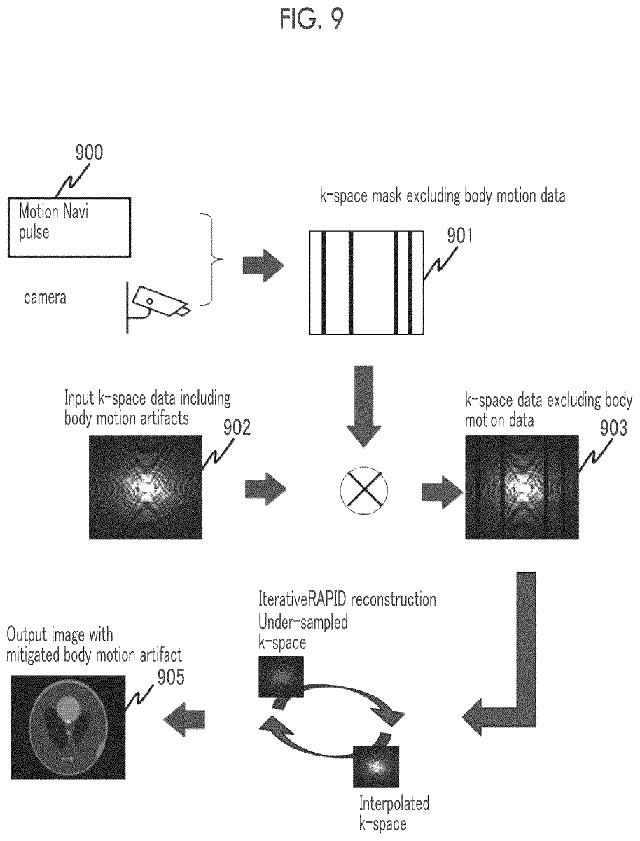

FIG. 9 is a conceptual diagram of one method of iterative reconstruction.

First, a mask 901 of data (removal data) to be removed from the measurement data is created using information 900 related to the body motion period generated by the body motion detection unit 230 and the body motion processing unit 240 from the navigator echo and the camera video, and image data 902 measured by the imaging unit 10 is multiplied by the mask 901 to obtain measurement data 903 excluding the removal data. The iterative reconstruction operation is an operation of minimizing a difference between the measurement data after interpolation and the undersampled measurement data while repeating interpolation and norm minimization in a sparse space with respect to the undersampled measurement data (or an image thereof), and it is possible to obtain an image 905 in which the removal data is interpolated and the consistency of the image information of the original measurement data is maintained. Re-measurement: S8

In a case in which the number or range of data to be removed is large and the image quality cannot be ensured even by using each of the above-described methods, the imaging controller 210 controls the imaging unit 10 to re-execute the imaging in the range. In this case, a UI for inputting the necessity of the re-measurement together with the range of the body motion-related data may be displayed on the user interface unit 70 (display device 40), and the user may select the necessity of the re-measurement. The re-measurement can be either a case of re-imaging or a case of only measuring the image signal lacking due to the removal data.

As described above, with the MRI apparatus of the present embodiment, the second period in consideration of the body motion detection timing error or the stabilization time of the echo signal after the body motion occurrence is set for the body motion period detected by the body motion detection means, and the data to be removed or corrected from the measurement data is specified based on the second period. Therefore, the influence of the body motion, which has been overlooked in the related art, can be removed, and an image in which the body motion artifact is reduced with high accuracy can be obtained.

In addition, according to the present embodiment, in a case in which the navigator data is used as the method of detecting the body motion, it is possible to determine the body motion detection and the stable state of the signal from the signal intensity of the navigator echo, and it is possible to reliably remove the data that affects the artifact each time the imaging is performed. Although the embodiments of the present invention have been described above, the sequence or pulse sequence for acquiring the navigator data and the image processing method for the measurement data having the missing data, which have been described as the embodiments, are merely examples, and various changes can be made within the scope of the present invention, and such changes are also included in the present invention.

### EXPLANATION OF REFERENCES

1: MRI apparatus
10: imaging unit
20: controller
80: camera
210: imaging controller
220: image generation unit
230: body motion detection unit
240: body motion processing unit

What is claimed is:

1. A magnetic resonance imaging apparatus comprising:
an RF transmitting unit that applies a high-frequency magnetic field pulse to an examination target placed in a static magnetic field space;
an RF receiving unit that receives a nuclear magnetic resonance signal emitted by the examination target;
a gradient magnetic field generation unit that generates a gradient magnetic field pulse for applying a magnetic field gradient to a static magnetic field; and
one or more processors that generate an image of the examination target using measurement data consisting of the nuclear magnetic resonance signal and process body motion information of the examination target,
wherein the one or more processors detect a first period during which a body motion occurs in the examination target, then specify a second period that includes the first period and that is longer than the first period, and remove or correct data collected in the second period in the measurement data to generate the image of the examination target.

2. The magnetic resonance imaging apparatus according to claim 1,
wherein the body motion information includes navigator data consisting of a plurality of navigator echoes acquired together with the measurement data, and
the one or more processors detect the first period from the navigator data.

3. The magnetic resonance imaging apparatus according to claim 2,
wherein the one or more processors detect the body motion occurring in the examination target from a change in intensity of the navigator echo.

4. The magnetic resonance imaging apparatus according to claim 2,
wherein the body motion information further includes a video or a signal of an optical detection device installed near the static magnetic field space, and
the one or more processors detect the body motion occurring in the examination target by using the navigator data and the video or the signal of the optical detection device in combination.

5. The magnetic resonance imaging apparatus according to claim 1,
wherein the one or more processors detect the body motion occurring in the examination target by using a video or a signal of an optical detection device installed near the static magnetic field space.

6. The magnetic resonance imaging apparatus according to claim 1,
wherein the one or more processors set a predetermined time in advance for at least one of a time before the first period or a time after the first period, and set the second period by adding the set time.

7. The magnetic resonance imaging apparatus according to claim 2,
wherein the one or more processors analyze a change in signal intensity of the navigator echo to specify the second period.

8. An image reconstruction method of magnetic resonance imaging, comprising:
defining, based on a result of detecting a body motion of an examination target disposed in a static magnetic field space, a period during which the body motion occurs as a first period, and specifying a second period that includes the first period and that is longer than the first period; and
removing or correcting data collected in the second period in measurement data of the examination target collected by the magnetic resonance imaging, and generating an image of the examination target.
